(19) United States
(12) Patent Application Publication
(10) Pub. No.: US 2006/0043575 A1
(43) Pub. Date: Mar. 2, 2006

(54) Chip module

(75) Inventors: Andreas Muller-Hipper, Regensburg (DE); Frank Puschner, Kelheim (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/216,457

(22) Filed: Aug. 30, 2005

(30) Foreign Application Priority Data
Aug. 31, 2004 (DE) 102004042145.5

(51) Int. Cl. H01L 23/12; H01L 23/28

(52) U.S. Cl. 257/704; 257/787; 257/731

(57) ABSTRACT

A chip module including a chip having an integrated circuit and a stiffening element which is connected to the chip. The stiffening element includes a first part which extends parallel to the connection plane of the chip, and at least one second part which extends at an angle to the plane. The chip is connected in a force-fitting manner to the first part of the stiffening element.

### CROSS-REFERENCE TO RELATED APPLICATION

This application claims priority to German Patent Application Serial No. 102004042145.5, which was filed on Aug. 31, 2004 and is incorporated herein by reference in its entirety.

### FIELD OF THE INVENTION

The invention relates to a chip module having a chip which comprises an integrated circuit.

### BACKGROUND OF THE INVENTION

Chip cards are usually constructed in such a manner that the electrical components are combined on a module which is considerably smaller than the chip card. During manufacture, the chip modules are inserted into corresponding recesses of a card body, and this arrangement is optionally provided with a covering sheet. In addition to the chip, chip modules having contacts comprise the requisite contact areas and connections between connection areas of the chip and the contact areas of the module. Contactless chip modules comprise the chip and an antenna or connections for an antenna.

More and more fields of application are being found for contactless chip cards, in particular. Contactless chip cards can be fitted in a flexible manner since they do not have to be in the immediate vicinity of a read/write unit in order to communicate with the latter, but rather it is possible to communicate over a relatively large distance. Contactless chip cards may be fitted such that they are visible or invisible. In addition, no problems arise as a result of the contacts being contaminated.

So-called e-documents, in particular the e-passport or “digital passport” in this case, are one of the new areas of application. Integrating the chip modules or the inlays (which are required for further lamination) in the e-documents, in particular, is associated with new demands on the chip modules or inlays.

In the case of an e-passport, a distinction is made between integration in the so-called cover page, that is to say the cover of the passport, and integration in the so-called holder page which is the page inside the passport which contains the passport holder's personal data.

Integrating conventional chip modules in the cover page does not constitute a major technical problem. However, the passport manufacturers wish to integrate the chip modules in the holder page in order to be able to combine electronic and written data on one page. The problem in this case is that conventional chip modules are too thick to be integrated in the holder page.

The prior art discloses a plurality of basic design variants of contactless chip modules which will be outlined briefly below.

In a first known variant, the chip is contact-connected using so-called wire bonds. A carrier having the chip and the wire bonds is surrounded by a plastic sheathing so that the wire bonds are not damaged. The large overall thickness of the chip module as a result of the chip being encapsulated is disadvantageous.

In a second variant, the chip is contact-connected using NiAu bumps in so-called flip-chip mounting so that there is no longer any need to cover the chip. In this case, the thickness of the module is primarily determined by the thickness of the chip. In order to manufacture very thin chip modules, it is known practice to implement the latter using contactless flip-chip technology and to use ultrathin chips in the process. This results in an overall thickness which is theoretically small enough to be able to integrate the chip modules in the holder page of an e-passport. However, these chip modules are highly susceptible to mechanical loading since they have low flexural stiffness and robustness on account of the small chip thickness. Therefore, reliable subsequent operation cannot be ensured.

In a third variant, the previously mentioned chip modules having only low flexural stiffness are adhesively bonded to a frame in order to stiffen them. Specifically, a frame is adhesively bonded onto a leadframe, for example. The disadvantage of this design variant is that adhesively bonding the frame requires an adhesive which is directly included in the overall thickness of the module. Typical frame heights are 300 micrometers, with the result that it is not possible to realize a small thickness of 150 micrometers, as is desired for use in e-passports. In addition, there is the risk of delamination between the frame and the leadframe.

Finally, it is known practice to adhesively bond a steel plate having a thickness of approximately 120 micrometers onto the chip. This increases the stability of the chip. The relatively large thickness of a chip module fabricated in this manner is disadvantageous. In addition, an antenna must be contact-connected directly on the chip, thus limiting freedom of design.

### SUMMARY OF THE INVENTION

A chip module including a chip having an integrated circuit and a stiffening element which is connected to the chip. The stiffening element includes a first part which extends parallel to the connection plane of the chip, and at least one second part which extends at an angle to the plane. The chip is connected in a force-fitting manner to the first part of the stiffening element.

### BRIEF DESCRIPTION OF THE DRAWINGS

The invention will be explained in more detail below with reference to an exemplary embodiment. In the drawing:

FIG. 1 shows a cross section of a first exemplary embodiment of a chip module according to the invention having a leadframe as a stiffening element;

FIG. 2 shows a plan view of the chip module of FIG. 1,

FIG. 3 shows a modified exemplary embodiment for use with an additional redistribution layer;

FIG. 4 shows a chip module which has been simplified in comparison with the illustration of FIG. 3;

FIG. 5 shows another exemplary embodiment of a chip module according to the invention having a cap as a stiffening element;

FIG. 6 shows contact-connection of the chip that is different to FIG. 5 in an alternative inlay construction;

FIG. 7 shows further different contact-connection of a chip in an alternative inlay construction;

FIG. 8 shows a laminate construction having a chip module as shown in FIG. 1;

FIG. 9 shows a laminate construction having a chip module as shown in FIG. 4;

FIG. 10 shows a laminate construction having a chip module as shown in FIG. 5;

FIG. 11 shows another laminate construction having a chip module as shown in FIG. 5;

FIG. 12 shows a laminate construction having a chip module as shown in FIG. 6; and

FIG. 13 shows a laminate construction having a chip module as shown in FIG. 7.

### DETAILED DESCRIPTION OF PREFERRED EMBODIMENTS OF THE INVENTION

It is an object of the invention to specify a very thin chip module which is nevertheless robust and flexurally stiff. It is to be possible, in particular, to provide a contactless, flexurally stiff chip module which has an overall thickness of approximately 150 micrometers and can thus be integrated in e-documents, in particular in the holder page of a digital passport.

This object is achieved by means of a chip module of the type mentioned initially, which chip module is distinguished by a stiffening element which is connected to the chip and has a first part which extends parallel to the connection plane of the chip, and at least one second part which extends at an angle to said plane, the chip being connected in a force-fitting manner to the first part of the stiffening element.

The advantage of a chip module according to the invention is that sufficient flexural stiffness can be achieved without the thickness of the chip module being increased to such an extent that it is no longer possible to integrate it in an e-document. It is advantageous if the angle between the first and second parts is between 45° and 90°. Particularly high flexural stiffness is achieved in this angular range. The angle is preferably 90°.

In a first advantageous refinement of the invention, the stiffening element is formed by a carrier element having carrier sections which have been stamped out or cut out and have been bent out of the plane of a first part of the carrier, said carrier sections forming the at least one second part of the stiffening element. A carrier element, for example a leadframe, which is present anyway can be changed in this manner such that it has increased stiffness and can thus be used as a stiffening element without additional elements being required. Instead of stamping out or cutting out, it is, of course, also possible to use other machining techniques in order to separate the carrier sections (which are to be bent out) from the rest of the carrier.

A chip module that is particularly flexurally stiff is achieved, in a development of the invention, by virtue of the fact that a plurality of second parts, together with the first part of the stiffening element, form a well in which the chip is arranged, and the well which has the chip arranged in it is filled with a covering compound.

In another advantageous refinement, the chip is arranged on a carrier element and is connected to the first part of a stiffening element on that side which is remote from the carrier element, the stiffening element forming a cap. The cap is therefore placed onto the chip and thus stiffens the chip without excessively increasing the height of the chip module.

The flexural stiffness achieved by using a cap is approximately as high as that of the continuous material of the same thickness without increasing the chip module by this thickness as a result. At the same time, the cap protects the sensitive side of the module which is at risk, in particular, in a typical holder page/laminate construction.

The refinement of the chip module in the two variants according to the invention makes it possible to process ultrathin chips, it being possible to fabricate ultrathin modules which can be integrated without any problems in e-documents, in particular the holder page of an e-passport. An additional advantage is that the problem (disclosed in the prior art) of delamination between a carrier and a frame cannot occur.

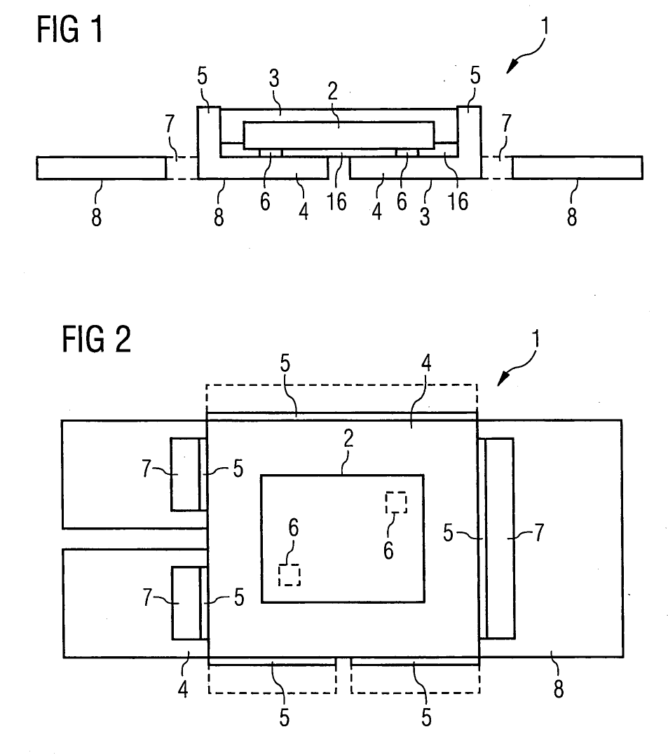

FIG. 1 shows a chip module according to the invention in which a leadframe 8 simultaneously forms a reinforcing element. The leadframe 8 has a first part 4 which lies in a plane parallel to the connection areas 6 of a chip 2. The first part 4 of the leadframe 8 is connected to the connection areas 6, for example by soldering. This produces an electrical and mechanical connection between the first part 4 of the leadframe and the chip 2. In the exemplary embodiment shown, provision is made of an adhesive layer 16 which produces an additional mechanical connection between the chip 2 and the leadframe 8. The leadframe 8 has a second part 5 comprising sections of the leadframe 8 which have been stamped out and bent out from the plane of the first part 4. In the exemplary embodiment of FIG. 1, a plurality of second parts 5 can be seen, one on the right-hand side and one on the left-hand side of the chip 2. In the sectional illustration shown, it can be seen that the leadframe 8 is interrupted in the center in order to electrically isolate the two connections of the chip. Those sections of the leadframe 8 which run on both sides of the first parts 4 are contact lugs. The two recesses lying in between are produced by virtue of the fact that the second parts 5 have been stamped out and bent out in these regions.

Surrounding the chip 2, the interspace between the two second parts 5 is filled with a potting compound 3. This further improves the mechanical properties of the module, it being possible to effect the potting operation using an extremely hard or else an extremely elastic compound, for example.

The angled arrangement of the first part 4 and the second part 5 of the leadframe 8 forms a stiffening element which has considerably higher flexural stiffness than the leadframe 8 in the flat state. It is possible to achieve flexural stiffness that is in the range of a solid leadframe having the height of the second parts 5 of the stiffening element 8. However, in the case of the construction of the chip module according to the invention, the thickness of the stiffening element 8 is not added to the thickness of a chip module of conventional construction but rather, as a result of the chip 2 being arranged between the second parts 5 of the stiffening element 8, the thickness of the entire chip module, including the stiffening element, remains very small.

FIG. 2 shows a plan view of the chip module of FIG. 1. In this diagrammatic illustration, it can easily be seen that the chip 2 is surrounded on all sides by second parts 5 of the stiffening element 8. Regions of the stiffening element 8 have been stamped out and bent upward to the right and left of the chip 2. As a result, recesses 7 which do not, however, have any particular disadvantages are produced in the stiffening element 8. Edge sections of the stiffening element 8 have been bent upward in the region of the other side areas of the chip 2, with the result that they form second parts 5 of the stiffening element 8. In this refinement of the invention, the chip 2 is surrounded by the second parts 5 which, in conjunction with the first part 4 of the stiffening element 8, form a well-shaped structure. Boundaries for the potting compound are thus conveniently formed during subsequent potting of the chip 2.

Lying below the chip 2 are the connection areas 6 of the chip which are connected to the first part 4 of the stiffening element there. This is expedient because the stiffening element 8 is formed by a leadframe which is also used to electrically contact-connect the chip 2.

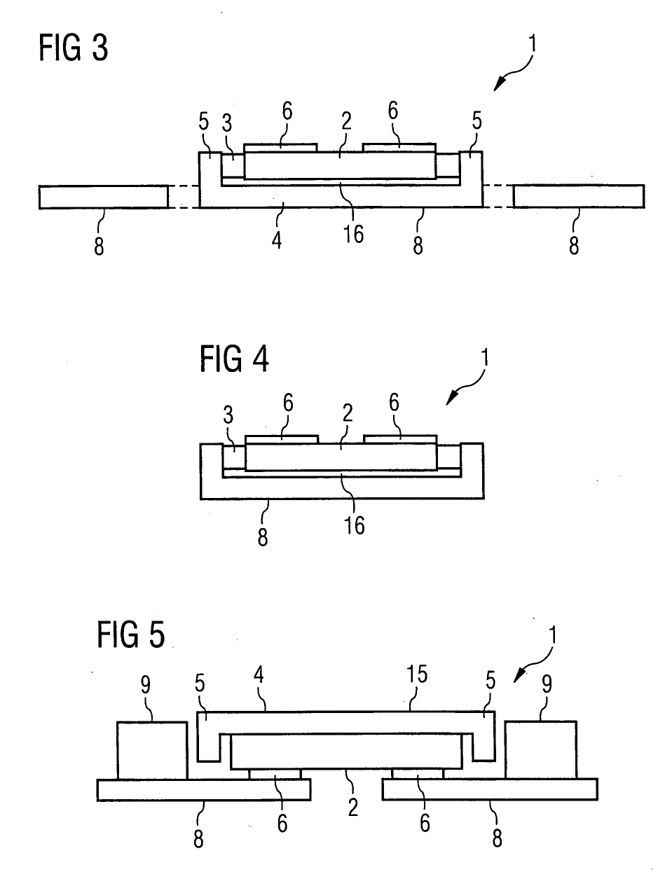

FIG. 3 shows a modified exemplary embodiment in which the chip 2 is not contact-connected using the leadframe or stiffening element 8 but rather use is made of a so-called redistribution layer. The connection areas 6 of the chip 2 are therefore situated on that side of the chip 2 which is remote from the stiffening element 8 so that they can be freely contact-connected at a later date. That side of the chip 2 which is remote from the connection areas 6 is adhesively bonded to the first part 4 of the stiffening element 8. Second parts 5 of the stiffening element 8 have been bent upward and thus, in turn, form a well-shaped structure, as was described with reference to FIGS. 1 and 2. The well is, in turn, filled with potting compound 3, the potting compound not extending over the chip 2 in this exemplary embodiment in order to leave the connection areas 6 clear for subsequent contact-connection.

The contact lugs (illustrated in FIG. 3) of the stiffening element 8 which is in the form of a leadframe are not actually required for a redistribution layer in a refinement having connection areas 6 at the top and may be omitted, as illustrated in FIG. 4.

FIG. 5 shows an alternative refinement of a stiffening element. A chip module 1 having a chip 2 that has been applied to a leadframe 8 has an additional stiffening element which is formed by a steel cap 15. The underside of the chip 2 is connected to the leadframe 8 via connection areas 6. The cap 15 is placed onto the top side of the chip 2 and is adhesively bonded to the latter there. The cap 15 has a first part 4 and a second part 5, the second part 5 being at an angle to the first part 4. This considerably increases the flexural stiffness and is not associated with any considerable increase in the thickness of the chip module 1 in this arrangement either. However, the chip module 1 is thicker than the embodiment of FIGS. 1 to 4 since the thickness of the leadframe 8 is added to the thickness of the material of the cap 15. Nevertheless, the overall thickness is so small that a chip module constructed in this manner can be used in an e-document, in particular an e-passport.

Epoxy elements 9 which, however, are optional and do not necessarily have to be provided in order to achieve the requisite flexural stiffness are provided on both sides (illustrated) of the arrangement having the chip 2 and the cap 15. They are used as insulation.

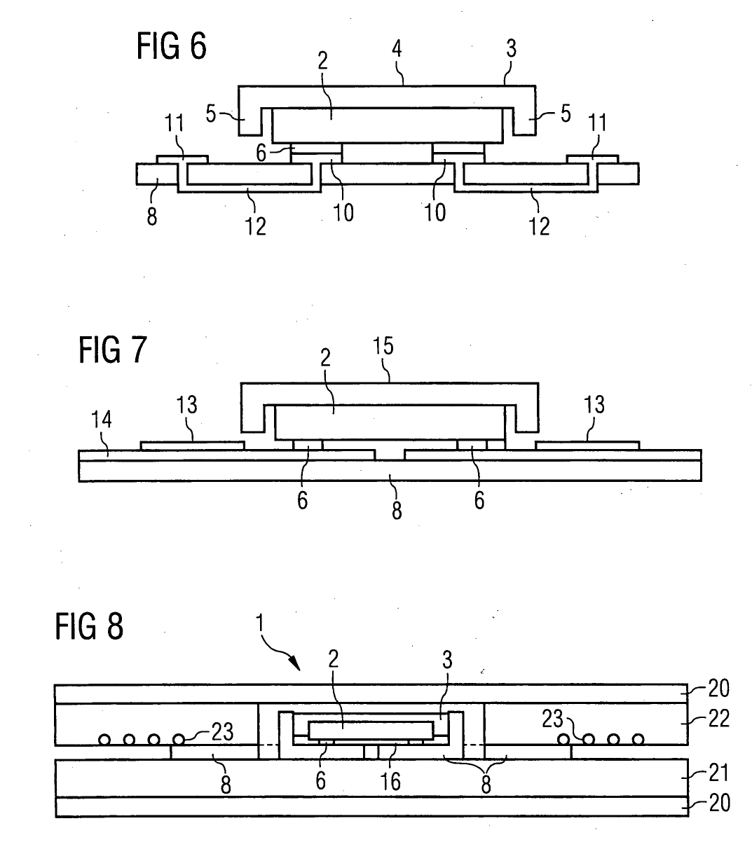

FIGS. 6 and 7 illustrate two variants on the arrangement of FIG. 5, the variations relating to the electrical contact-connection of the connection areas 6 of the chip 2 and to different possible inlay constructions. Whereas, in the module shown in FIG. 5, use was made of a leadframe comprising a conductive material which, for this reason, can also be electrically connected to the connection areas 6 and is used as a connecting element, a nonconductive carrier 8 is provided in the refinement shown in FIG. 6. Contact areas 10 and 11 which are provided, on the one hand, for contact-connecting the connection areas 6 of the chip and, on the other hand, for connecting an antenna, for example, are arranged on the top side of the carrier 8. Connecting lines 12 which are each connected to the contact areas 10 and 11 via through-plating are used to electrically connect the contact areas 10 and 11. The contact areas 10 and 11 are thus connected on the underside of the carrier 8.

A nonconductive carrier 8 is likewise provided in the arrangement of FIG. 7. Metallizations 14 which are connected to the connection areas 6 of the chip 2 are applied to said carrier, a plurality of metallized regions being separated from one another in order to be able to separately connect the connection areas 6. In the metallization areas 14, regions are covered with an insulating sheet 13 so that conductive elements can be arranged without being in electrical contact with the metallization areas 14 as a result of resting on top of the latter.

FIG. 8 shows the layer construction of a laminate as can be used, for example, in the holder page of an e-passport. In this case, use is made of a chip module as is illustrated in FIG. 1. The leadframe 8 rests on top of a paper layer 21. The contact lugs of the leadframe 8 are each electrically connected to a turn of an antenna 23. The leadframe 8 which, in the exemplary embodiment shown, simultaneously forms the stiffening element electrically connects the antenna 23 and connection areas 6 of the chip 2. The chip module 1 is embedded in a recess of a sheet 22, for example a PE (polyethylene) sheet. The PE sheet lies above the paper layer 21 and above the leadframe 8. The thickness of the sheet 22 is dimensioned in such a manner that it is at least as thick as the leadframe 8 which forms a stiffening element. A covering sheet 20 is provided above the described arrangement, with the result that there is a planar area toward the outside and the chip module 1 is protected. A covering sheet 20 which forms a protective layer for the paper layer 21 and the chip module 1 lying above the latter and may also be printed on in order to configure the external appearance is likewise provided below the paper layer 21.

Although forces which act on the layer arrangement shown in FIG. 8 are transmitted to the chip module 1, the flexural stiffness of the chip module 1 is so high, on account of the stiffening element 8, that the chip 2 is not damaged and the electrical connection between the connection areas 6 of the chip 2 and the leadframe 8 is not impermissibly loaded either.

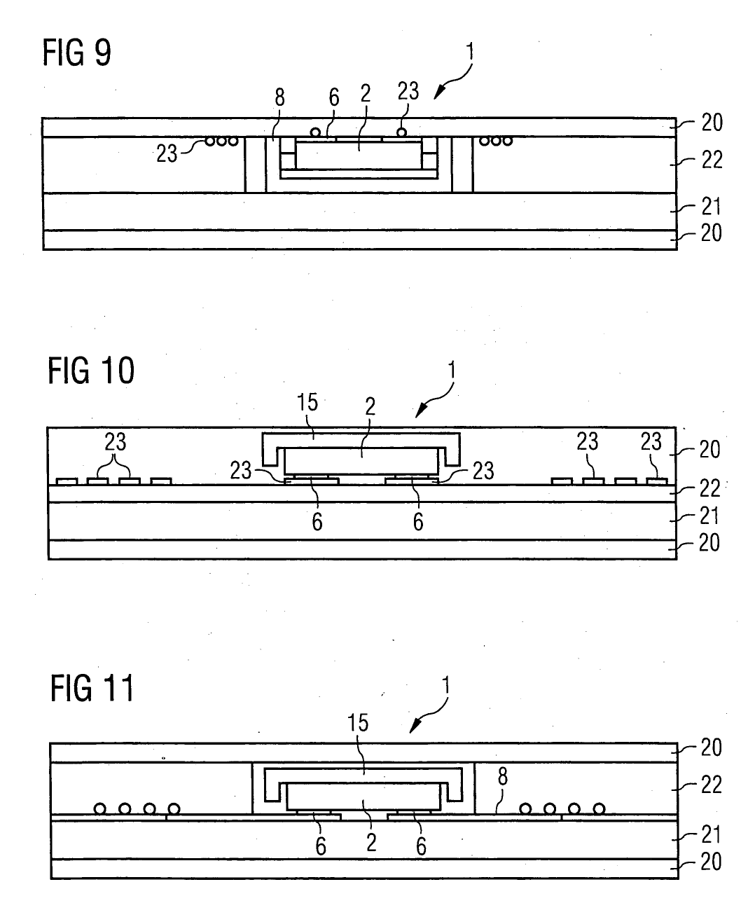

FIG. 9 shows one possible layer construction if a chip module as shown in FIG. 4 is used. In this arrangement, the leadframe 8 only has the function of forming a stiffening element but not of electrically contact-connecting connection areas 6 of the chip 2. Instead of this, the connection areas 6 at the top of the chip 2 are directly connected to connections of an antenna 23. The other turns of the antenna lie further to the outside on a PE sheet 22, a covering sheet 20 which covers the top side of the layer construction being arranged above said PE sheet. A paper layer 21 whose surface is likewise protected by a covering sheet 20 is, in turn, provided below the chip module 1.

Direct contact-connection between connection areas 6 of the chip 2 and the antenna 23 is also possible if the chip module 1 is formed in accordance with the embodiment of FIGS. 5 to 7, that is to say has a cap 15 as a stiffening element. In the layer arrangement shown in FIG. 10, turns of an antenna 23 are formed on a PE sheet 22. In this case, the PE sheet 22 forms a carrier for the chip module 1. Two ends of the antenna turns are routed in such a manner that they are directly contact-connected by connection areas 6 of the chip 2.

In the embodiment of FIG. 11, a leadframe 8 forms a carrier for the chip module 1. Inner regions of the leadframe 8 are connected to connection areas 6 of the chip 2, while outer regions are connected to turns of the antenna 23.

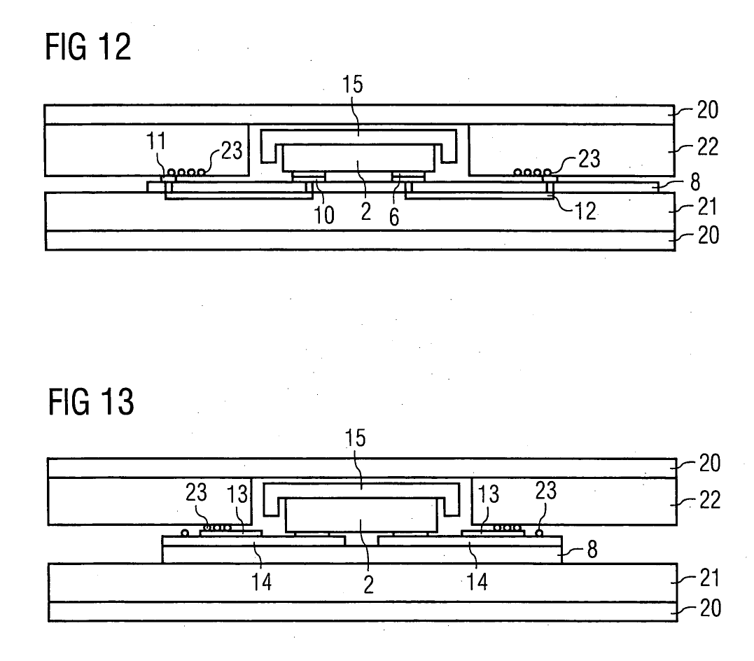

The layer construction of FIG. 12 has been modified insofar as a leadframe 8 which is itself conductive is not provided but rather connection areas 6 of the chip 2 and turns of the antenna 23 are conductively connected via conductor tracks 12 on the underside of a nonconductive leadframe 8, as was described with reference to FIG. 6. In this exemplary embodiment too, the cap 15 can be arranged without the contact-connection of the chip 2 being hindered.

FIG. 13 shows a layer construction having a chip module 1 which is constructed as shown in FIG. 7. It can easily be seen from this exemplary embodiment that the insulating elements 13 can be used to arrange turns of an antenna 23 in such a manner that they are insulated from metallizations of a carrier 8. In this case, two ends of the turns of the antenna 23 are arranged in a respective metallization area 14 in order to produce an electrical connection to the chip 2.

The exemplary embodiments described were explained with reference to diagrammatic illustrations. It goes without saying that the actual proportions will differ from the illustrations shown. Further modifications of the exemplary embodiments shown are possible and are included in the present invention.

What is claimed is:

1. A chip module comprising:
a chip having an integrated circuit; and
a stiffening element which is connected to the chip and includes:
a first part which extends parallel to the connection plane of the chip; and
at least one second part which extends at an angle to the plane,
wherein the chip is connected in a force-fitting manner to the first part of the stiffening element.

2. The chip module as claimed in claim 1, wherein the stiffening element is formed by a carrier element having carrier sections which have been stamped out or cut out and have been bent out of the plane of a first part of the carrier, the carrier sections forming the at least one second-part of the stiffening element.

3. The chip module as claimed in claim 2, wherein the carrier element is a leadframe which electrically contact-connects the chip, and connection areas of the chip are connected to the leadframe.

4. The chip module as claimed in claim 2, wherein the side of the chip which is remote from connection areas of the chip is connected to a leadframe, and the connection areas of the chip are electrically connected to a coupling element via an additional connecting plane.

5. The chip module as claimed in claim 1, wherein a plurality of second parts, together with the first part, form a well in which the chip is arranged, and the well which has the chip is filled with a potting compound.

6. The chip module as claimed in claim 1, wherein the chip is arranged on a carrier element and is connected to the first part of the stiffening element on that side of the chip which is remote from the carrier element, the stiffening element forming a cap.

7. The chip module as claimed in claim 1, wherein the stiffening element is nonconductive and further includes:
contact areas for contact-connecting connection areas of the chip; and
connecting lines electrically connecting the contact areas.

8. The chip module as claimed in claim 1, wherein the stiffening element is nonconductive and further includes:
metallization areas connected to connection areas of the chip; and
an insulating sheet covering the metallization areas.

9. The chip module as claimed in claim 6, wherein the stiffening element is composed of steel.

10. The chip module as claimed in claim 1, wherein the angle between the first part and the at least one second part is between 45° and 90°.

11. The chip module as claimed in claim 1, further comprising epoxy elements formed on the stiffening element on both sides of the chip.

12. A laminate comprising the chip module of claim 1.

13. The laminate of claim 12, further comprising:
a PE sheet, wherein the chip module is embedded in a recess of the PE sheet; and
a coupling element,
wherein the stiffening element connects the coupling element and connection areas of the chip.

14. A laminate comprising the chip module of claim 4.

15. The laminate of claim 14, further comprising:
a PE sheet, which forms a carrier for the chip module; and
a coupling element formed on the PE sheet, wherein ends of the coupling element are connected directly to connection areas of the chip.

16. A laminate comprising the chip module of claim 6.

17. The laminate of claim 16, further comprising a coupling element connected directly to connection areas of the chip.

18. The laminate of claim 16, further comprising a coupling element, wherein inner regions of the stiffening element are connected to connection areas of the chip and outer regions of the stiffening element are connected to the coupling element.

19. The laminate of claim 16, further comprising:
a coupling element; and
conductor tracks,
wherein connection areas of the chip and the coupling element are connected on the underside of the stiffening element via the conductor tracks.
